(19) United States
(12) Patent Application Publication
(10) Pub. No.: US 2021/0197310 A1
(43) Pub. Date: Jul. 1, 2021

(54) LASER PROCESSING APPARATUS

(71) Applicant: DISCO CORPORATION, Tokyo (JP)

(72) Inventor: Fumiya KAWANO, Tokyo (JP)

(21) Appl. No.: 17/122,077

(22) Filed: Dec. 15, 2020

(30) Foreign Application Priority Data
Dec. 27, 2019 (JP) 2019-238020

(51) Int. Cl. B23K 26/03; B23K 26/70

(52) U.S. Cl. CPC B23K 26/032; B23K 26/707

(57) ABSTRACT

A laser processing apparatus includes a laser beam applying unit, an imaging unit, and a processing section. The processing unit includes a histogram generating section and a determining section. The histogram generating section generates, from an image obtained by the imaging unit imaging a plurality of processing marks formed by applying the laser beam from the laser beam applying unit to a one-surface side of the workpiece, a first histogram including a plurality of first positions along a first direction of the image and brightness at each of the first positions and a second histogram including a plurality of second positions along a second direction orthogonal to the first direction and brightness at each of the second positions. The determining section determines a boundary of each region where one of the processing marks is formed, based on the first histogram and the second histogram generated by the histogram generating section.

### BACKGROUND OF THE INVENTION

### Field of the Invention

The present invention relates to a laser processing apparatus that applies a laser beam to one-surface side of a workpiece to thereby form a plurality of processing marks, and a method for confirming each region where one of the plurality of processing marks is present.

### Description of the Related Art

In a laser processing apparatus that applies a laser beam having such a wavelength as to be absorbed by a workpiece to the workpiece to process the workpiece, a shape of the laser beam influences processing quality. The shape of the laser beam is confirmed, for example, by observing results of processing after actually processing the workpiece by the laser beam. In an example, in a case where a one-surface side of a flat plate-shaped workpiece is processed in a linear manner by a laser beam, first, another surface side located opposite to the one surface of the workpiece is held by a holding table provided in the laser processing apparatus. Next, the holding table is moved in a predetermined direction substantially orthogonal to a laser beam applying direction to process the one-surface side of the workpiece in a linear manner by the laser beam (see, for example, Japanese Patent Laid-open No. 2013-78785).

At the time of processing, a condenser lens for concentrating the laser beam is positioned at a plurality of different heights to form a plurality of linear processing marks according to each height. For example, the condenser lens is disposed at a first height to form a linear first processing mark. Next, the condenser lens is disposed at a second height different from the first height, and the laser beam is applied to a region different from a region of the first processing mark to form a linear second processing mark. After a plurality of linear processing marks are formed on the one-surface side of the workpiece, a width of each processing mark is observed, so that the shape of the laser beam is confirmed.

Incidentally, there are cases where a plurality of dot-shaped processing marks are formed on an upper surface of a workpiece to thereby confirm the shape of the laser beam. In these cases, first, an image of the upper surface formed with the plurality of dot-shaped processing marks is obtained. Next, based on the image, detection of outlines of the processing marks, decision of acceptability of the shape of the laser beam, and the like are performed. However, if the detection of the outlines, the decision of acceptability, and the like are carried out by a person, huge time is required for the processing operation. In addition, a criterion for determining a boundary between a processing region and a non-processing region, a criterion for the decision of acceptability, and the like may vary according to the operator. In view of this, it is conceivable to automatically carry out the processing operations by use of a laser processing apparatus. For example, it is conceivable that, first, coordinates of boundaries of a plurality of small regions each including one processing mark are designated by the operator, and image processing or the like is performed to each small region, thereby to automatically detect the outlines of the processing marks.

### SUMMARY OF THE INVENTION

However, it is necessary to designate the coordinates of the boundaries every time the position of a processing mark changes, and the operation can be performed only by an operator with expertise; further, it takes time for the operation. The present invention has been made in consideration of such problems. It is an object of the present invention to automatically determine boundaries of a plurality of small regions where processing marks are formed in an image by a laser processing apparatus, without designation of the coordinates of the boundaries of the regions by an operator.

In accordance with an aspect of the present invention, there is provided a laser processing apparatus including a laser beam applying unit that applies a laser beam having such a wavelength as to be absorbed by a workpiece to thereby process the workpiece, an imaging unit for imaging the workpiece, and a processing section that processes an image obtained by imaging the workpiece by the imaging unit. The processing section includes a histogram generating section and a determining section. The histogram generating section generates, from an image obtained by the imaging unit imaging a plurality of processing marks formed by applying the laser beam from the laser beam applying unit to a one-surface side of the workpiece, a first histogram including a plurality of first positions along a first direction of the image and brightness at each of the first positions and a second histogram including a plurality of second positions along a second direction orthogonal to the first direction and brightness at each of the second positions. The determining section determines a boundary of each region where one of the plurality of processing marks is formed, based on the first histogram and the second histogram generated by the histogram generating section.

Preferably, the histogram generating section generates the first histogram by, at each of the first positions, summing up values indicative of a measure of brightness of a plurality of pixels located on a straight line passing through the first position and being parallel to the second direction and generates the second histogram by, at each of the second positions, summing up values indicative of a measure of brightness of a plurality of pixels located on a straight line passing through the second position and being parallel to the first direction.

In addition, preferably, the processing section further includes an outline detecting section that detects an outline of each of the plurality of processing marks by generating, for the region, a third histogram representing brightness of a plurality of pixels on each of a plurality of straight lines located at different positions in the second direction and being parallel to the first direction and a fourth histogram representing brightness of a plurality of pixels on each of a plurality of straight lines located at different positions in the first direction and being parallel to the second direction.

In accordance with another aspect of the present invention, there is provided a method for applying a laser beam to a one-surface side of a workpiece by use of a laser processing apparatus to thereby form a plurality of processing marks and then confirming each region where one of the plurality of processing marks is formed. The method includes: a processing mark forming step of applying a laser beam having such a wavelength as to be absorbed by the workpiece to the workpiece to thereby form the plurality of processing marks on the one-surface side of the workpiece; an imaging step of imaging the plurality of processing marks formed in the processing mark forming step to obtain an image; a histogram generating step of, by a processing section of the laser processing apparatus, generating a first histogram including a plurality of first positions along a first direction of the image and brightness at each of the first positions and a second histogram including a plurality of second positions along a second direction orthogonal to the first direction and brightness at each of the second positions; and a determining step of, by the processing section, determining a boundary of each region where one of the plurality of processing marks is formed, based on the first histogram and the second histogram generated in the histogram generating step.

Preferably, in the histogram generating step, the processing section generates the first histogram by, at each of the first positions, summing up values indicative of a measure of brightness of a plurality of pixels located on a straight line passing through the first position and being parallel to the second direction and generates the second histogram by, at each of the second positions, summing up values indicative of a measure of brightness of a plurality of pixels located on a straight line passing through the second position and being parallel to the first direction.

Besides, preferably, the method further includes an outline detecting step of, by the processing section, detecting an outline of each of the plurality of processing marks by generating, for the region, a third histogram representing brightness of a plurality of pixels on each of a plurality of straight lines located at different positions in the second direction and being parallel to the first direction and a fourth histogram representing brightness of a plurality of pixels on each of a plurality of straight lines located at different positions in the first direction and being parallel to the second direction.

The laser processing apparatus according to one aspect of the present invention includes the processing section that processes the image including the plurality of processing marks. The processing section has the histogram generating section. The histogram generating section generates, from the image, the first histogram including the plurality of first positions along the first direction of the image and the brightness at each of the first positions and the second histogram including the plurality of second positions along the second direction orthogonal to the first direction and the brightness at each of the second positions. The processing section further has the determining section. The determining section determines the boundary of each region where one of the plurality of processing marks is present, based on the histograms of brightness generated by the histogram generating section. Therefore, the boundaries of the regions where the processing marks are formed can be automatically determined by the laser processing apparatus.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a laser processing apparatus;

FIG. 2 is a schematic diagram of an image including a plurality of processing marks;

FIG. 3 is a flow chart of a method according to a first embodiment;

FIG. 4A is a diagram for explaining a histogram generating step;

FIG. 4B is a diagram for explaining a determining step;

FIG. 5 is a diagram for explaining an outline detecting step; and

FIG. 6 is a diagram depicting a histogram generating step and a determining step according to a second embodiment.

### DETAILED DESCRIPTION OF THE PREFERRED EMBODIMENTS

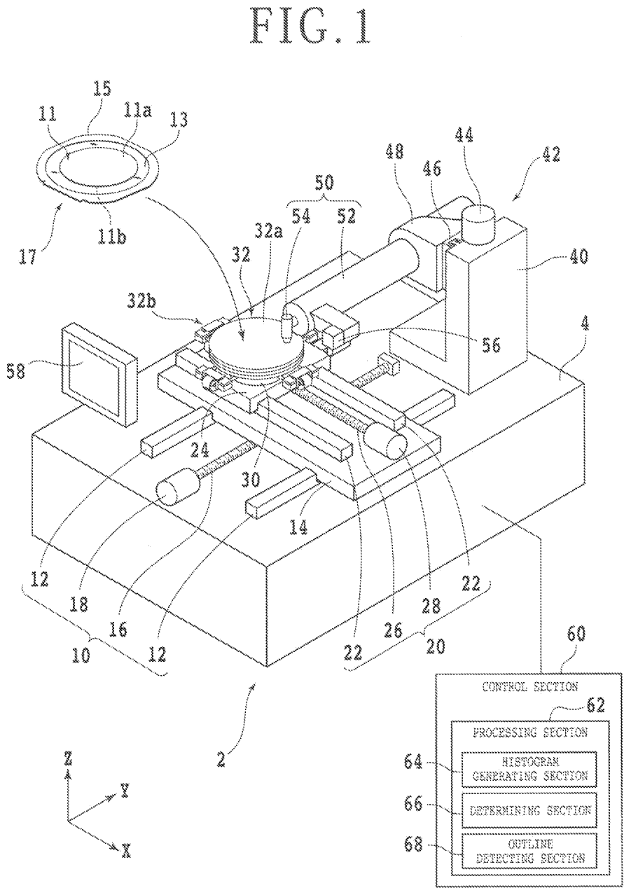

An embodiment according to one mode of the present invention will be described referring to the attached drawings. FIG. 1 is a perspective view of a laser processing apparatus 2. Note that, in FIG. 1, part of components of the laser processing apparatus 2 are depicted as functional blocks. In addition, an X-axis direction (a left-right direction, a processing feeding direction, a first direction), a Y-axis direction (a front-rear direction, an indexing feeding direction, a second direction), and a Z-axis direction (a vertical direction, a height direction) are orthogonal to one another.

The laser processing apparatus 2 includes a rectangular parallelepiped base 4 that supports each component. A Y-axis direction moving unit 10 is provided on an upper surface of the base 4. The Y-axis direction moving unit 10 has a pair of Y-axis guide rails 12 extending in parallel to the Y-axis direction. The pair of Y-axis guide rails 12 are fixed on the upper surface of the base 4. A Y-axis moving table 14 is slidably attached to the pair of Y-axis guide rails 12. A nut section (not illustrated) is provided on a back surface side (lower surface side) of the Y-axis moving table 14.

A Y-axis ball screw 16 disposed in parallel to the Y-axis guide rails 12 is connected to the nut section in a rotatable manner. In addition, a Y-axis pulse motor 18 is connected to one end of the Y-axis ball screw 16. When the Y-axis ball screw 16 is rotated by the Y-axis pulse motor 18, the Y-axis moving table 14 is moved in the Y-axis direction along the Y-axis guide rails 12. An X-axis direction moving unit 20 is provided on an upper surface side of the Y-axis moving table 14.

The X-axis direction moving unit 20 has a pair of X-axis guide rails 22 extending in parallel to the X-axis direction. The pair of X-axis guide rails 22 are fixed on an upper surface of the Y-axis moving table 14. An X-axis moving table 24 is slidably attached to the pair of X-axis guide rails 22. A nut section (not illustrated) is provided on a lower surface side of the X-axis moving table 24, and an X-axis ball screw 26 disposed in parallel to the X-axis guide rails 22 is connected to the nut section in a rotatable manner. An X-axis pulse motor 28 is connected to one end of the X-axis ball screw 26.

When the X-axis ball screw 26 is rotated by the X-axis pulse motor 28, the X-axis moving table 24 is moved in the X-axis direction along the X-axis guide rails 22. A cylindrical table base 30 is fixed on an upper surface side of the X-axis moving table 24. A substantially disk-shaped chuck table 32 is provided at an upper portion of the table base 30. A rotational drive source (not illustrated) such as a motor provided in the table base 30 is connected to the chuck table 32.

The chuck table 32 can be rotated around a rotational axis substantially parallel to the Z-axis direction by a force generated by the rotational drive source. The chuck table 32 has a metallic frame body. The frame body includes, on an upper portion side thereof, a recess (not illustrated) having a disk-shaped space. One end of a flow channel (not illustrated) for sucking a gas or the like is connected to the recess. In addition, a suction source (not illustrated) such as an ejector is connected to another end of the flow channel. A disk-shaped porous plate (not illustrated) is fixed to the recess of the frame body.

When the suction source is operated, a negative pressure is generated at an upper surface (holding surface 32a) of the porous plate. A workpiece 11 or the like is placed on the holding surface 32a. The workpiece 11 is formed, for example, of silicon, and has a disk-like shape including one surface 11a and another surface 11b that are both substantially flat. Note that the material of the workpiece 11 is not limited to silicon, and the workpiece 11 may be formed of other material. Besides, the workpiece 11 may be a laminated substrate in which a plurality of substrates (for example, a silicon substrate and a sapphire substrate) formed of different materials are adhered to each other.

A resin-made protective tape 13 larger in diameter than the workpiece 11 is adhered to the other surface 11b side of the workpiece 11. The protective tape 13 has, for example, a laminated structure of a base material layer and an adhesive layer, and the adhesive layer side is adhered to the other surface 11b of the workpiece 11. A metallic annular frame 15 with an opening having a diameter larger than an outside diameter of the workpiece 11 is adhered to a peripheral portion of the protective tape 13. In this way, a workpiece unit 17 in which the workpiece 11 is supported by the frame 15 through the protective tape 13 is formed. The workpiece 11 is carried and processed in the form of the workpiece unit 17.

A plurality of clamps 32b are provided at lateral sides of the frame body of the chuck table 32. After the workpiece unit 17 is placed on the holding surface 32a such that the one surface 11a is located on an upper side and the other surface 11b is located on a lower side, the frame 15 is clamped by each of the clamps 32b. A tetragonal prismatic support section 40 is fixed on an upper surface of the base 4 in a vicinity of an end portion on one side (rear side) in the Y-axis direction of the base 4. A Z-axis direction moving unit 42 is provided at a side surface on one side in the X-axis direction of the support section 40.

The Z-axis direction moving unit 42 has a pair of Z-axis guide rails extending substantially in parallel to the Z-axis direction. Each of the Z-axis guide rails is fixed on a one-side surface of the support section 40. A Z-axis moving plate 46 is slidably attached to the Z-axis guide rails. A nut section (not illustrated) is provided on a back surface side (namely, on the support section 40 side) of the Z-axis moving plate 46, and a Z-axis ball screw (not illustrated) disposed in parallel to the Z-axis guide rails is connected to the nut section in a rotatable manner.

A Z-axis pulse motor 44 is connected to one end of the Z-axis ball screw. When the Z-axis ball screw is rotated by the Z-axis pulse motor 44, the Z-axis moving plate 46 is moved in the Z-axis direction along the Z-axis guide rails. A holder 48 is fixed to a front surface side (a side opposite to the back surface) of the Z-axis moving plate 46. The holder 48 has a cylindrical cavity section of which a height direction is parallel to the Y-axis direction. A cylindrical casing 52 is fixed to the cavity section. The casing 52 constitutes a laser beam applying unit 50.

The laser beam applying unit 50 includes a laser oscillator (not illustrated) that generates a pulsed laser beam by laser oscillation. The laser oscillator has a rod-shaped laser medium formed of, for example, Nd:YAG or Nd:YVO₄. The laser beam emitted from the laser oscillator is incident on a light concentrator 54 provided at an end portion on another side (front side) in the Y-axis direction of the casing 52, through optical parts such as a laser beam adjusting unit (not illustrated) and a mirror. A condenser lens (not illustrated) for concentrating the laser beam is provided inside the light concentrator 54.

An optical axis of the condenser lens is disposed substantially in parallel to the Z-axis direction, and the laser beam emitted from the condenser lens is applied substantially perpendicularly to the holding surface 32a. In one example, the laser beam has such a wavelength as to be absorbed by the workpiece 11 (for example, a wavelength of 355 nm), a repetition frequency of 20 kHz to 50 kHz, and an average output of 3.0 W to 6.0 W. A camera unit (imaging unit) 56 is provided on another side in the X-axis direction of the casing 52. The camera unit 56 is, for example, a visible light camera, and has an objective lens (not illustrated) and an imaging element (not illustrated) that receives visible light from a subject through the objective lens. The imaging element is, for example, a complementary metal oxide semiconductor (CMOS) image sensor or a charge coupled device (CCD) image sensor.

The upper side of the base 4 is covered with a cover section (not illustrated), and an input-output unit 58 is provided at a side surface on the front side of the cover section. The input-output unit 58 is, for example, a touch panel. The input-output unit 58 functions as both an input section used when the operator inputs processing conditions or the like and a display section for displaying the processing conditions, images, and the like. The laser processing apparatus 2 has a control section 60 that controls each component. The control section 60 controls operations of the Y-axis direction moving unit 10, the X-axis direction moving unit 20, the rotational drive source, the suction source, the Z-axis direction moving unit 42, the laser beam applying unit 50, and the like.

The control section 60 includes a computer having, for example, a processing unit such as a central processing unit (CPU), a main storage unit such as a dynamic random access memory (DRAM), and an auxiliary storage unit such as a flash memory and a hard disk drive. With the processing unit and the like operated according to a software stored in the auxiliary storage unit, functions of the control section 60 are realized. The control section 60 has a processing section 62 that processes an image captured by the camera unit 56. The processing section 62 is, for example, a software such as a program that is executed by being read by the above-described processing unit. Note that the processing section 62 is not limited to a software, but may be a hardware such as an application-specific integrated circuit (ASIC).

The processing section 62 has a histogram generating section 64. The histogram generating section 64 generates a histogram in which a position of each of pixels aligned along a predetermined direction among a plurality of pixels constituting an image is taken on an axis of abscissa, and brightness of the pixels is taken on an axis of ordinate. For example, the histogram generating section 64 generates a first histogram in which the position in the X-axis direction (first direction) is taken on the axis of abscissa, and a summed-up value of values indicative of a measure of brightness of a plurality of pixels aligned in a row along the Y-axis direction is taken on the axis of ordinate.

In addition, the histogram generating section 64 generates a second histogram in which the position in the Y-axis direction (second direction) is taken on the axis of abscissa, and a summed-up value of values indicative of a measure of brightness of a plurality of pixels aligned in a row along the X-axis direction is taken on the axis of ordinate. The processing section 62 further has a determining section 66 that determines a general range of each of processing marks discretely present in an image. For example, in a case where the processing marks are brighter than a background of an image, the determining section 66 specifies positions in the first histogram and the second histogram where the summed-up value of brightness is comparatively low.

Next, the determining section 66 sets virtual straight lines passing through the positions in the X-axis direction where the summed-up value is comparatively low and being parallel to the Y-axis direction, and virtual straight lines passing through the positions in the Y-axis direction where the summed-up value is comparatively low and being parallel to the X-axis direction, thereby partitioning the image into small regions. The processing section 62 further has an outline detecting section 68 that detects an outline of a processing mark with respect to a small region defined by the determining section 66. The outline detecting section 68 in the present embodiment detects, for the small region, the outline of a processing mark by generating a third histogram indicative of the brightness of a plurality of pixels aligned in a row along the X-axis direction and a fourth histogram indicative of the brightness of a plurality of pixels aligned in a row along the Y-axis direction.

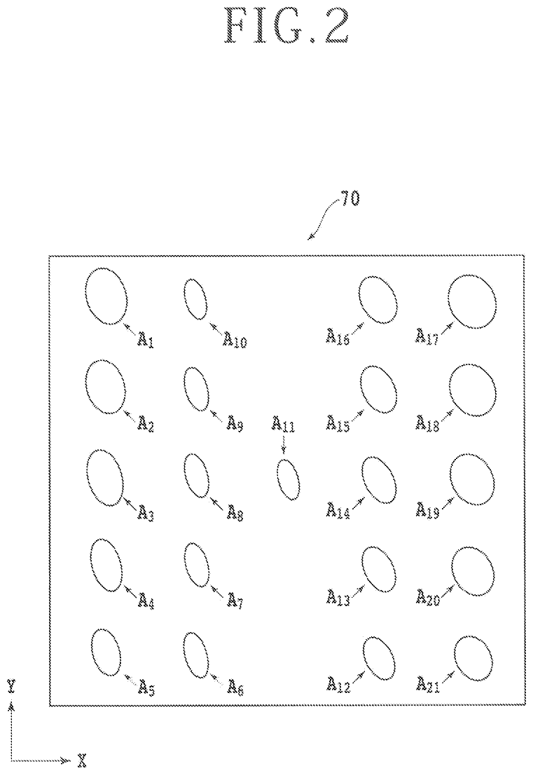

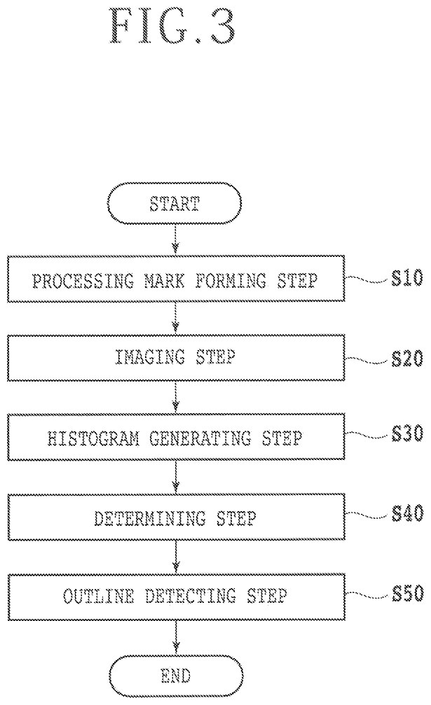

Next, a method for forming processing marks A (see FIG. 2) on the one surface 11a side of the workpiece 11 by use of the laser processing apparatus 2 and confirming each region where one of the processing marks A is formed, is described. FIG. 3 is a flow chart of the method according to a first embodiment. In this method, first, a processing mark forming step S10 is conducted. In the processing mark forming step S10, the workpiece 11 and the like are held by the chuck table 32 in such a manner that the one surface 11a is exposed to the upper side, after which a pulsed laser beam is applied to the one surface 11a side to process the workpiece 11.

In the present embodiment, after one processing mark A is formed on the one surface 11a side, the application of the laser beam is once stopped. Then, the chuck table 32 is moved in at least either one direction of the X-axis direction and the Y-axis direction relative to the light concentrator 54 to change the laser beam applying position. After the applying position is changed, again, another processing mark A is formed on the one surface 11a side. In this way, twenty-one processing marks A (processing marks A₁ to A₂₁ depicted in FIG. 2) are formed at different positions on the one surface 11a side.

Note that, in the present embodiment, at the time of changing the applying position, the condenser lens of the light concentrator 54 is positioned at different heights. Specifically, for the processing mark A₁, a focal point of the laser beam is positioned inside the workpiece 11. In addition, every time the applying position is changed, the focal point is moved stepwise upward, so that the processing marks A₂, A₃, A₄, . . . , and A₁₀ are sequentially formed. Next, at the time of forming the processing mark Aₙ, laser processing is conducted in a state in which the focal point is positioned on the one surface 11a that is located above the height of the focal point at the time of forming the processing mark A₁₀.

Thereafter, the focal point is moved stepwise upward every time the applying position is changed, so that the processing marks A₁₂, A₁₃, A₁₄, . . . , and A₂₁ are sequentially formed. In other words, at the time of forming the processing marks A₁₂, . . . , and A₂₁, the focal point is positioned above the one surface 11a. After the processing mark forming step S10, an imaging step S20 is performed. In the imaging step S20, the one surface 11a is imaged by the camera unit 56 to obtain an image 70 including all the processing marks A formed.

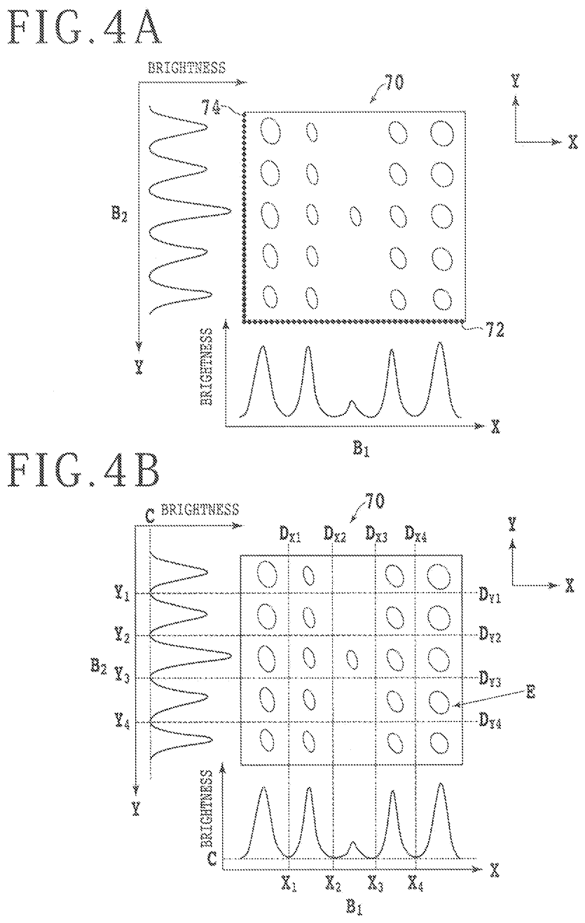

FIG. 2 is a schematic diagram of the image 70 including a plurality of processing marks A. The processing marks A in the present embodiment are displayed to be brighter than the background in the image 70. Note that the image 70 may be a multi-valued image represented in gray scale or in full color, or may be a binary image represented in black and white. After the imaging step S20, a histogram generating step S30 is conducted. In the histogram generating step S30, the histogram generating section 64 generates, from the image 70, a first histogram B₁ representing the brightness at a plurality of first positions 72 (see FIG. 4A) arranged along the X-axis direction.

The first histogram B₁ in the present embodiment is generated by, at each of the first positions 72, summing up values indicative of a measure of brightness of a plurality of pixels located on a straight line passing through the first position 72 and being parallel to the Y-axis direction. FIG. 4A is a diagram for explaining the histogram generating step S30. Note that the number of the first positions 72 depicted in FIG. 4A is illustrative, and the number may be more than this. The axis of abscissa of a graph depicted on the lower side in FIG. 4A represents the X coordinate, and the axis of ordinate of the graph represents the brightness. Each processing mark A in the present embodiment is displayed to be brighter than a region where no processing mark A is formed, and therefore, the value indicative of the measure of brightness is higher as the number of pixels located at the processing marks A on the straight line passing through the first position 72 and being parallel to the Y-axis direction is larger.

The histogram generating section 64 further generates, from the image 70, a second histogram B₂ representing the brightness at a plurality of second positions 74 arranged along the Y-axis direction. Note that the number of the second positions 74 depicted in FIG. 4A is illustrative, and the number may be larger than this. The second histogram B₂ in the present embodiment is generated by, at each of the second positions 74, summing up values indicative of a measure of brightness of a plurality of pixels located on a straight line passing through the second position 74 and being parallel to the X-axis direction. The axis of abscissa of a graph depicted on the left side in FIG. 4A represents the Y-coordinate, and the axis of ordinate of the graph represents the brightness.

After the histogram generating step S30, based on the first histogram B₁ and the second histogram B₂ thus generated, the determining section 66 determines a boundary of each region, where one of the processing marks A is formed, discretely present in the image 70 (determining step S40). The determining section 66 in the present embodiment specifies the first positions 72 (X₁, X₂, X₃, and X₄ depicted in FIG. 4B) where the brightness is a low value C such as a minimal value or a minimum value in the first histogram B₁. Then, the determining section 66 partitions the image 70 by a plurality of virtual straight lines D (D_{X1}, D_{X2}, D_{X3}, and D_{X4} depicted in FIG. 4B) that pass through the first positions 72 where the brightness is the value C and are parallel to the Y-axis direction. Similarly, the determining section 66 specifies the second positions 74 (Y₁, Y₂, Y₃, and Y₄ depicted in FIG. 4B) where the brightness is a low value C such as a minimal value or a minimum value in the second histogram B₂. Then, the determining section 66 partitions the image 70 by a plurality of virtual straight lines D (D_{Y1}, D_{Y2}, D_{Y3}, and D_{Y4} depicted in FIG. 4B) that pass through the second positions 74 where the brightness is the value C and are parallel to the X-axis direction.

FIG. 4B is a diagram for explaining the determining step S40. The axis of abscissa of a graph depicted on the lower side in FIG. 4B represents the X coordinate, and the axis of ordinate of the graph represents the brightness. In addition, the axis of abscissa of a graph depicted on the left side in FIG. 4B represents the Y coordinate, and the axis of ordinate of the graph represents the brightness. In the example illustrated in FIG. 4B, the value C is common for the first histogram B₁ and the second histogram B₂. In addition, the image 70 is partitioned in a grid pattern by the plurality of straight lines D_{X1}, D_{X2}, D_{X3}, and D_{X4} and the plurality of straight lines D_{Y1}, D_{Y2}, D_{Y3}, and D_{Y4}, so that a plurality of small regions E are formed.

It is highly possible that the processing mark A is present in each small region E. In the present embodiment, in this way, the boundary of each region where one of processing marks A is formed can be automatically determined by the laser processing apparatus 2. In other words, the small regions E including the processing marks A are automatically determined. Therefore, it is unnecessary to designate coordinates corresponding to the boundaries of the small regions E every time the positions of the processing marks A change. In addition, since the boundaries of the small regions E are automatically determined by the laser processing apparatus 2, the operation can be performed by an operator without expertise.

Note that, in the first histogram B₁, a peak located between X₂ and X₃ is smaller than other peaks. On the other hand, in the second histogram B₂, a peak located between Y₂ and Y₃ is larger than other peaks. Therefore, the processing section 62 can decide that, between X₂ and X₃, the processing mark A is present only in a small region E surrounded by four points of (X₂, Y₂), (X₂, Y₃), (X₃, Y₂), and (X₃, Y₃), based on the difference in the peaks.

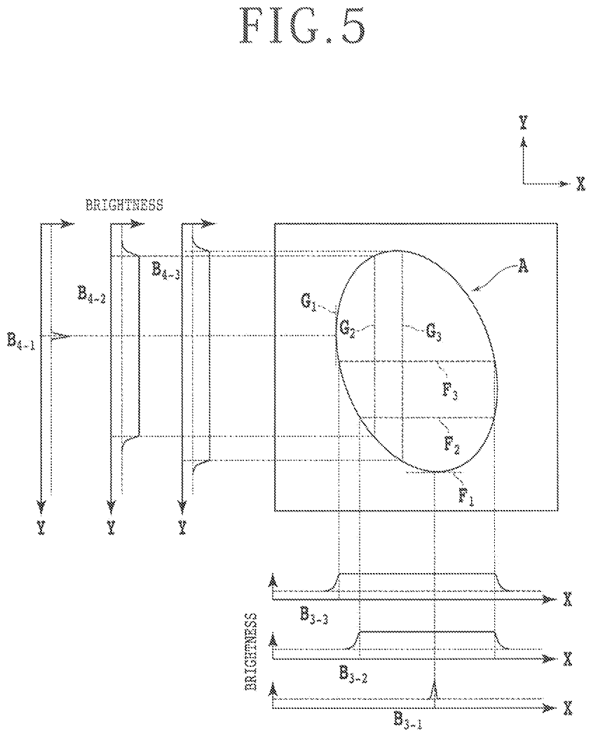

After the determining step S40, the outline detecting section 68 detects the outline of each processing mark A (outline detecting step S50). FIG. 5 is a diagram for explaining the outline detecting step S50. Note that, in FIG. 5, a schematic diagram of the outline of one processing mark A is depicted. The outline detecting section 68 generates a third histogram B₃ and a fourth histogram B₄ for each small region E. The third histogram B₃ represents the brightness of a plurality of pixels on each of a plurality of straight lines F that are located at different positions in the Y-axis direction and are parallel to the X-axis direction.

In FIG. 5, three third histograms B₃₋₁, B₃₋₂, and B₃₋₃ representing the brightness of pluralities of pixels on three straight lines F₁, F₂, and F₃ are illustrated. The axis of abscissa of each third histogram B₃ represents the X coordinate, and the axis of ordinate represents the brightness. The fourth histogram B₄ represents the brightness of a plurality of pixels on each of a plurality of straight lines G that are located at different positions in the X-axis direction and are parallel to the Y-axis direction. In FIG. 5, three fourth histograms B₄₋₁, B₄₋₂, and B₄₋₃ representing the brightness of pluralities of pixels on three straight lines G₁, G₂, and G₃ are illustrated. The axis of abscissa of each fourth histogram B₄ represents the Y coordinate, and the axis of ordinate represents the brightness. A rise-up position (that is, the X coordinate and the Y coordinate) of the third histogram B₃ and the fourth histogram B₄ corresponds to an edge of a processing mark A. By connecting together the rise-up positions, the outline of the processing mark A is specified. Note that, as an alternative technique, the outline detecting section 68 may specify the outline of a processing mark A by use of such a technique as edge detection.

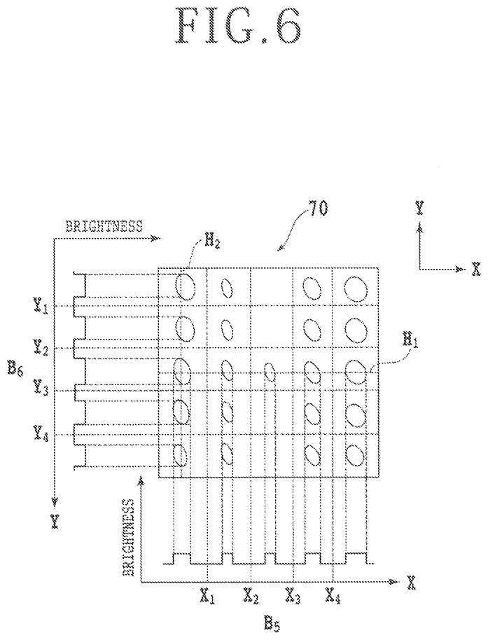

Next, a second embodiment will be described. In the second embodiment, in the histogram generating step S30, the histogram generating section 64 does not sum up values indicative of the measure of brightness of a plurality of pixels. In addition, in the determining step S40, the determining section 66 determines the boundaries by use of peaks, rise-ups, and the like, instead of minimal values and the like. In such a point, the second embodiment differs from the first embodiment. FIG. 6 is a diagram depicting the histogram generating step S30 and the determining step S40 according to the second embodiment. The histogram generating section 64 in the second embodiment generates a fifth histogram B₅ that represents the X coordinate (axis of abscissa) and the brightness (axis of ordinate) by a straight line H₁ along the X-axis direction. The fifth histogram B₅ is a histogram on the straight line H₁ that is located at the third in the Y-axis direction and passes through five processing marks A aligned along the X-axis direction.

Next, in a case where a plurality of peaks, rise-ups (edges), or the like are present in the fifth histogram B₅, the determining section 66 sets, as a boundary of a small region E, an intermediate position between two adjacent peaks or an intermediate position between edges adjacent to each other with a valley therebetween. Note that, in a case where peaks, edges or the like are not present in the fifth histogram B₅, the histogram generating section 64 repeats generation of the fifth histogram B₅ by moving the straight line H₁ in the Y-axis direction until the peaks, edges or the like are obtained.

The histogram generating section 64 similarly generates a sixth histogram B₆ that represents the Y coordinate (axis of abscissa) and the brightness of the pixel (axis of ordinate) on a straight line H₂ along the Y-axis direction. The sixth histogram B₆ is a histogram on the straight line H₂ that is located at the first in the X-axis direction and passes through five processing marks A aligned along the Y-axis direction. Next, in a case where a plurality of peaks, rise-ups (edges), or the like are present in the sixth histogram B₆, the determining section 66 sets, as a boundary of a small region E, an intermediate position between two adjacent peaks or an intermediate position between edges adjacent to each other with a valley therebetween. Note that, in a case where peaks, edges or the like are not present in the sixth histogram B₆, the histogram generating section 64 repeats generation of the sixth histogram B₆ by moving the straight line H₂ in the X-axis direction until the peaks, edges or the like are obtained.

The structures, methods, and the like according to the above embodiments can be modified as required insofar as the modifications do not depart from the scope of the object of the present invention. For example, after the outline detecting step S50, the processing section 62 may calculate an area of each region where one processing mark A is formed, a center of balance of each processing mark A, deviation of each processing mark A from a true circle, and the like. As a result, a shape of the laser beam, a state of the laser processing apparatus 2, and the like can be diagnosed.

Incidentally, while an example in which the processing marks A are displayed to be brighter than the background in the image 70 has been described in the above embodiments, the processing marks A may be displayed to be darker than the background in the image 70. In this case, the darkness and brightness are reversed in each histogram, and therefore, contents of processing by the processing section 62 are appropriately adjusted according to the first or second embodiment. Note that the method of confirming the processing marks A as described above is conducted, for example, at the time of processing the workpiece 11 on a trial basis before applying laser lift off processing to the workpiece 11 by use of the laser processing apparatus 2.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing apparatus comprising:
a laser beam applying unit that applies a laser beam having such a wavelength as to be absorbed by a workpiece to thereby process the workpiece;
an imaging unit for imaging the workpiece; and
a processing section that processes an image obtained by imaging the workpiece by the imaging unit,
wherein the processing section includes
a histogram generating section that generates, from an image obtained by the imaging unit imaging a plurality of processing marks formed by applying the laser beam from the laser beam applying unit to a one-surface side of the workpiece, a first histogram including a plurality of first positions along a first direction of the image and brightness at each of the first positions and a second histogram including a plurality of second positions along a second direction orthogonal to the first direction and brightness at each of the second positions, and
a determining section that determines a boundary of each region where one of the plurality of processing marks is formed, based on the first histogram and the second histogram generated by the histogram generating section.

2. The laser processing apparatus according to claim 1,
wherein the histogram generating section
generates the first histogram by, at each of the first positions, summing up values indicative of a measure of brightness of a plurality of pixels located on a straight line passing through the first position and being parallel to the second direction, and
generates the second histogram by, at each of the second positions, summing up values indicative of a measure of brightness of a plurality of pixels located on a straight line passing through the second position and being parallel to the first direction.

3. The laser processing apparatus according to claim 1,
wherein the processing section further includes
an outline detecting section that detects an outline of each of the plurality of processing marks by generating, for the region, a third histogram representing brightness of a plurality of pixels on each of a plurality of straight lines located at different positions in the second direction and being parallel to the first direction and a fourth histogram representing brightness of a plurality of pixels on each of a plurality of straight lines located at different positions in the first direction and being parallel to the second direction.

4. A method for applying a laser beam to a one-surface side of a workpiece by use of a laser processing apparatus to thereby form a plurality of processing marks and then confirming each region where one of the plurality of processing marks is formed, the method comprising:
a processing mark forming step of applying a laser beam having such a wavelength as to be absorbed by the workpiece to the workpiece to thereby form the plurality of processing marks on the one-surface side of the workpiece;
an imaging step of imaging the plurality of processing marks formed in the processing mark forming step to obtain an image;
a histogram generating step of, by a processing section of the laser processing apparatus, generating a first histogram including a plurality of first positions along a first direction of the image and brightness at each of the first positions and a second histogram including a plurality of second positions along a second direction orthogonal to the first direction and brightness at each of the second positions; and
a determining step of, by the processing section, determining a boundary of each region where one of the plurality of processing marks is formed, based on the first histogram and the second histogram generated in the histogram generating step.

5. The method according to claim 4,
wherein, in the histogram generating step, the processing section
generates the first histogram by, at each of the first positions, summing up values indicative of a measure of brightness of a plurality of pixels located on a straight line passing through the first position and being parallel to the second direction, and
generates the second histogram by, at each of the second positions, summing up values indicative of a measure of brightness of a plurality of pixels located on a straight line passing through the second position and being parallel to the first direction.

6. The method according to claim 4, further comprising:
an outline detecting step of, by the processing section, detecting an outline of each of the plurality of processing marks by generating, for the region, a third histogram representing brightness of a plurality of pixels on each of a plurality of straight lines located at different positions in the second direction and being parallel to the first direction and a fourth histogram representing brightness of a plurality of pixels on each of a plurality of straight lines located at different positions in the first direction and being parallel to the second direction.
